(19) United States
(12) Patent Application Publication
(10) Pub. No.: US 2026/0079048 A1
(43) Pub. Date: Mar. 19, 2026

(54) TUNABLE FIBER SCANNER FOR ALL-FIBER NONLINEAR MICROSPECTROMETER AND PREPARATION METHOD THEREOF

(71) Applicant: TIANJIN UNIVERSITY, Tianjin (CN)

(72) Inventors: Junfeng JIANG, Tianjin (CN); Jianing ZHANG, Tianjin (CN); Kun LIU, Tianjin (CN); Shuang WANG, Tianjin (CN); Tiegen LIU, Tianjin (CN)

(21) Appl. No.: 19/327,084

(22) Filed: Sep. 12, 2025

(30) Foreign Application Priority Data
Sep. 18, 2024 (CN) 2024113003196

(51) Int. Cl. G01J 3/02; G01J 3/06; G02B 26/10; H10N 30/071; H10N 30/20; H10N 30/853; H10N 30/87; H10N 39/00

(52) U.S. Cl. CPC G01J 3/0218; G01J 3/0256; G01J 3/06; G02B 26/103; H10N 30/071; H10N 30/2042; H10N 30/853; H10N 30/875; H10N 39/00; G01J 2003/068; G01J 2003/069

(57) ABSTRACT

The present disclosure discloses a tunable fiber scanner for an all-fiber nonlinear microspectrometer, including a scanning fiber, a scanning unit and a driving unit; the scanning unit includes a micro scanning square tube, the scanning fiber is fixed in the center of the micro scanning square tube, and the fiber ferrule is slidable relative to the scanning fiber so as to form an optical fiber cantilever; the spiral regulator controls the scanning fiber to generate lateral movement to obtain a controllable length of the optical fiber cantilever; the driving unit includes a piezoelectric ceramic driver arranged outside the scanner, the piezoelectric ceramic driver applies amplified driving signal to the micro scanning square tube, and the micro scanning square tube receives the amplified driving signal to drive the scanning fiber to scan and drive the optical fiber cantilever to perform resonance scanning.

### CROSS-REFERENCE TO RELATED APPLICATION

This application claims priority from the Chinese patent application 2024113003196 filed Sep. 18, 2024, the content of which is incorporated herein in the entirety by reference.

### TECHNICAL FIELD

The present disclosure relates to the field of nonlinear fiber optics and fiber scanning, in particular to a four-piece assembled tunable piezoelectric-driven fiber scanner for an all-fiber nonlinear microspectrometer.

### BACKGROUND ART

A nonlinear optical imaging is an imaging technology that generates image contrast based on a nonlinear optical effect of interaction between light and substance, and is widely applied to the research of living organisms. The Coherent Anti-Stokes Raman Scattering (CARS) microscopic imaging technology can obtain the molecular composition and distribution of the sample to be detected according to the vibration or rotation characteristics of the substance molecule without external marking, and has good chemical specificity. The integrated probe module is very important in CARS microscopy, and the scanning characteristics of the scanner in the probe directly determine system imaging field of view, resolution, and frame rate. The near-end scanning scheme in which the scanner is located outside the endoscopic probe can reduce the difficulty of probe design and packaging, the fiber core distance can limit the resolution of system imaging, not to mention the pulse broadening during femtosecond pulse transmission needs to be compensated through a complex dispersion compensation module. The remote scanning scheme in which the scanner device is located inside the endoscopic probe is divided into micro-electro-mechanical system (MEMS) scanning and piezoelectric ceramic driving fiber scanning. Most of the scanning schemes of the MEMS scanning galvanometer need to be imaged by means of optical path folding, which faces significant challenges in reducing the lateral dimensions; in contrast, the piezoelectric ceramic driving fiber scanning has the advantages of compact structure, small size, capability of realizing full optical fiber and the like. However, a high-quality miniature piezoelectric ceramic tubular structure and an electrode are very difficult to manufacture.

### SUMMARY OF THE DISCLOSURE

The present disclosure aims at providing a tunable fiber scanner for an all-fiber nonlinear microspectrometer and a preparation method thereof. The present disclosure forms a micro scanning tubular tube by assembling four tunable piezoelectric ceramic chips. The piezoelectric ceramic driver applies a compensated driving signal to the micro scanning tubular tube, so that the scanning fiber performs resonance scanning along with the vibration of the micro piezoelectric ceramic chips.

In order to fulfill the above objective, the present disclosure has the following technical solutions:

A tunable fiber scanner for an all-fiber nonlinear microspectrometer comprises a fiber connector, a scanning fiber, a micro scanning square tube, a fiber ferrule, a spiral regulator, a piezoelectric ceramic driver, a fixing collar, and a packaging sleeve; wherein the micro scanning square tube is assembled by four micro piezoelectric ceramic chips; the fiber ferrule is tightly sleeved in the micro scanning square tube, and the scanning fiber is relatively in slidable connection with the fiber ferrule; the scanning fiber is fixed in the micro scanning square tube by the fiber ferrule; the scanning fiber is located in the center of the micro scanning square tube; the fiber connector is connected with the scanning fiber; the spiral regulator is fixed at the front end of the scanning fiber; and the rear end of the scanning fiber penetrates through the interior of the fiber ferrule to form an optical fiber cantilever; and the spiral regulator controls the scanning fiber to generate lateral movement to obtain a controllable length of the optical fiber cantilever; the piezoelectric ceramic driver is arranged outside the scanner, and is composed of a signal generator and an amplifier; wherein the signal generator is used for generating an alternating current signal to obtain a driving signal required for the scanning fiber; and the driving signal comprises a scanning range and a scanning track mode which are used for driving the scanning fiber; the amplifier is used for amplifying the driving signal outputted by the signal generator; the piezoelectric ceramic driver applies a compensated driving signal to the micro scanning square tube, so that the scanning fiber performs resonance scanning along with vibration of the micro piezoelectric ceramic chips, and the micro scanning square tube drives the optical fiber cantilever to perform resonance scanning; and the fixing collar and the packaging sleeve are used for fixing and packaging the tunable fiber scanner.

A preparation method of the tunable fiber scanner for an all-fiber nonlinear microspectrometer comprises the following steps:

Step 1: embedding rubber into plastic clay, exposing edges of right angles of the rubber, evenly applying a small amount of epoxy resin glue on the edges of the two micro piezoelectric ceramic chips, then adding the amount of the glue to the edges where the micro piezoelectric ceramic chips are connected, and fixing for 24 hours to form a stable L-shaped structure;

Step 2: placing the L-shaped structure in a groove of the glass mold, one micro piezoelectric ceramic chip of the L-shaped structure is tightly attached to the glass of the glass mold, the other micro piezoelectric ceramic chip is above the groove; placing the fiber ferrule under the L-shaped structure, tightly attached to the glass, and supporting the L-shaped structure; evenly applying epoxy resin glue on the edges of a third micro piezoelectric ceramic chip and placing the third micro piezoelectric ceramic chip on the other side of the L-shaped structure, tightly attaching to the fiber ferrule and the micro piezoelectric ceramic chip located on the top, and fixing for 24 hours to form a U-shaped groove;

Step 3: cutting after peeling off a coating at one end of the scanning fiber, so as to ensure the smoothness of an end of the optical fiber cantilever; inserting the scanning fiber into the fiber ferrule to a specific cantilever length; placing the fiber ferrule with the scanning fiber in the upside-down U-shaped groove, and fixing the fiber ferrule and U-shaped groove by epoxy resin glue; placing a fourth micro piezoelectric ceramic chip onto the top of the U-shaped groove, evenly applying epoxy resin glue on the edges of the fourth micro piezoelectric ceramic chip to fix the fourth micro piezoelectric ceramic chip and the U-shaped groove, and fixing for 24 hours to form a stable micro scanning square tube;

Step 4: fixing a cylindrical nut at the rear end of the micro scanning square tube by the epoxy resin glue, penetrating the scanning fiber through the micro scanning square tube, and configuring a screw to construct the spiral regulator; fixing the fixing collar at the tail end of the micro scanning square tube by the epoxy resin glue, a certain space is reserved to lead out a wire; and fixing the packaging sleeve and the fixing collar to ensure that a 0-scale marking position on the outer wall of the packaging sleeve is capable of aligning with the marking position of the spiral regulator when the screw is screwed tightly and the optical fiber cantilever reached maximum length, so as to form a four-piece assembled tunable piezoelectric-driven fiber scanner.

Compared with the prior art, the present disclosure has the following technical advantages:
(1) The four-piece assembled tunable piezoelectric-driven fiber scanner is manufactured by using four micro piezoelectric ceramic chips and applied with a mold-assisted preparation process, the scanner does not use an independent tubular structure vibration device having a relatively high processing complexity such as a piezoelectric ceramic tube; the scanner of the present disclosure has the advantages such as easy mass production, low cost, and high electrical parameter control level;
(2) The four-piece assembled structure of the scanner enables the interior of the scanner to conveniently fix fiber ferrules with different sizes, ensures the outer diameter of the fiber ferrule fits the width of the micro piezoelectric ceramic chips; and the fiber ferrule significantly enhances the central symmetry and stability of the system;
(3) the size of the micro piezoelectric ceramic chips and types of the fiber can be adjusted during the preparation of the scanner, which has great significant to the practical application;
(4) the scanner can achieve the tuning of the vibration amplitude of the tail end of the optical fiber by applying different compensated voltage signals by means of the piezoelectric ceramic driver according to different imaging fields, scanning range, imaging frame rate and scanning speed requirements, the scanner can also achieve the tuning of the resonance frequency of the optical fiber cantilever by changing its length by means of the spiral regulator, thereby improving the application flexibility of the scanner;
(5) the scanner of the present disclosure has a small size and excellent performance, and is expected to become a new paradigm of optical microscopic imaging applications for life science research and clinical medical applications.

### BRIEF DESCRIPTION OF THE DRAWINGS

FIGS. 1A-1D are schematic structural diagrams of a tunable fiber scanner for an all-fiber nonlinear microspectrometer according to the present disclosure, FIG. 1A shows a schematic structural diagram of a tunable fiber scanner for an all-fiber nonlinear microspectrometer, FIG. 1B shows a detailed structural diagram of part A in FIGS. 1A, 1C shows a detailed structural diagram of part B in FIG. 1A, and 1D shows a detailed structural diagram of part C in FIG. 1A;

FIG. 2 is an enlarged diagram of the marking positions of the scanner and the spiral regulator;

FIG. 3 shows the preparation of forming a L-shaped structure;

FIG. 4 is a side view of preparing the scanner by using a glass mold;

FIG. 5 is an overall view of preparing the scanner by using a glass mold.

### REFERENCE SIGNS

1: fiber connector; 2: scanning fiber; 3: micro scanning square tube; 4: fiber ferrule; 21: front end; 22: optical fiber cantilever; 31,32,33,34: micro piezoelectric ceramic chip; 35: wire; 5: spiral regulator; 6: piezoelectric ceramic driver; 7: fixing collar; 8: packaging sleeve; 9: epoxy resin glue; 10: plastic clay; 11: rubber; 12: glass mold; 121,122,123: glass plate; 13: nonlinear microscopic imaging excitation source; 14: hole; 15: nut; 16: screw; 17: handle.

### DETAILED DESCRIPTION OF THE EMBODIMENTS

The technical solution of the present disclosure will be described in detail with reference to accompanying drawings and embodiments.

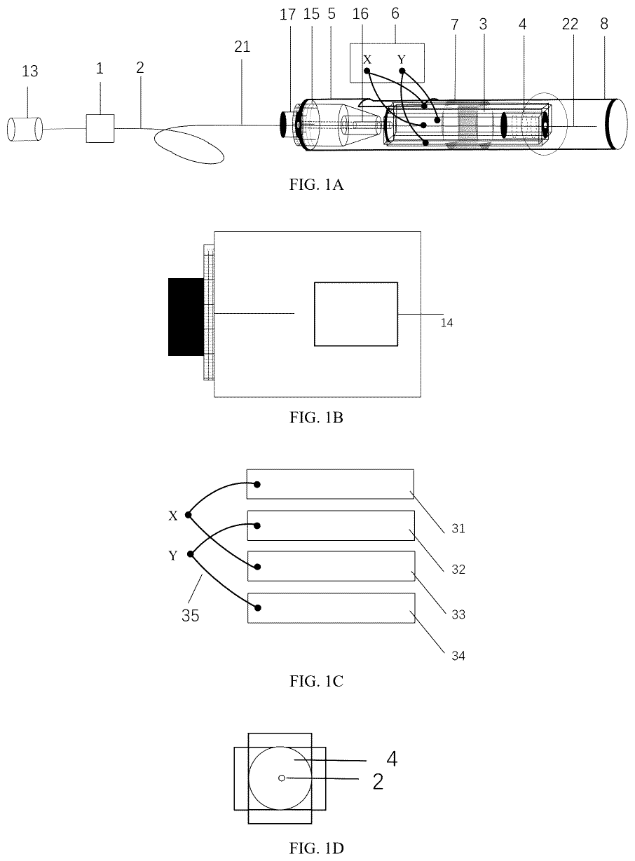

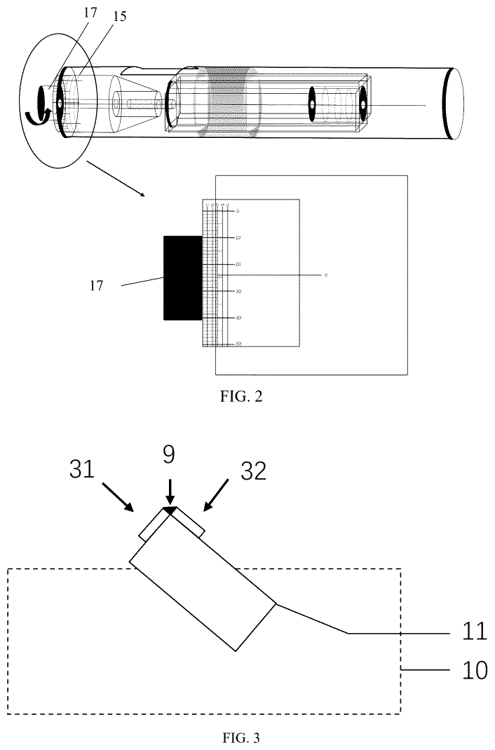

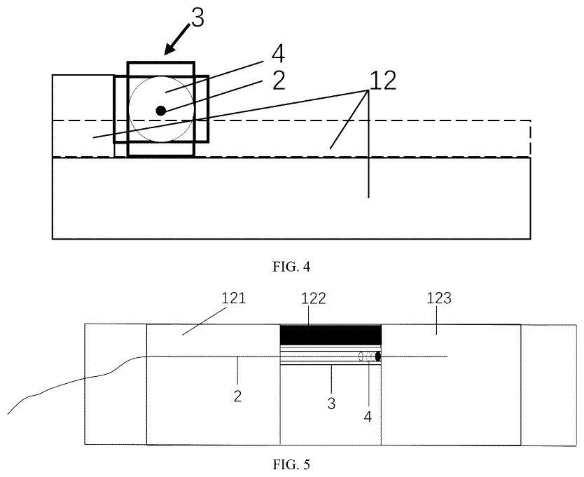

As shown in FIG. 1, a tunable fiber scanner for an all-fiber nonlinear microspectrometer comprises a scanning unit and a driving unit;

A front end of a scanning fiber is fixed with a spiral regulator 5, the spiral regulator controls the scanning fiber to generate lateral movement to obtain a controllable length of the optical fiber cantilever;

The scanning unit comprises a micro scanning square tube, the micro scanning square tube is assembled by four micro piezoelectric ceramic chips; a fiber ferrule is tightly sleeved in the micro scanning square tube, and the rear end of a scanning fiber penetrates through the interior of the fiber ferrule to fix in the center of the micro scanning square tube; the fiber ferrule is slidable relative to the scanning fiber so as to form an optical fiber cantilever; and the spiral regulator controls the scanning fiber to generate lateral movement to obtain a controllable length of the optical fiber cantilever.

The driving unit comprises a piezoelectric ceramic driver arranged outside the scanner, the piezoelectric ceramic driver comprises a signal generator and an amplifier; wherein the signal generator is used for generating a driving signal, the amplifier is used for amplifying the driving signal outputted by the signal generator; the piezoelectric ceramic driver applies amplified driving signal to the micro scanning square tube 3, and the micro scanning square tube receives the amplified driving signal to drive the scanning fiber to scan and drive the optical fiber cantilever to perform resonance scanning.

The micro scanning square tube 3, which acts as a core component of the scanner, is an assembled structure assembled by four micro piezoelectric ceramic chips 31,32,33,34. The fiber ferrule 4 is tightly sleeved in the micro scanning square tube 3, and the scanning fiber 2 is fixed in the micro scanning square tube 3 by the fiber ferrule 4 so as to ensure the scanning fiber 2 is fixedly located in the center of the micro scanning square tube, thus enhancing the central symmetry and stability of the scanner and increasing the scan quality, The fiber connector 1 is connected with the scanning fiber 2. The spiral regulator 5 is fixed at the front end of the scanning fiber 2, and rear end of the scanning fiber 2 penetrates through the interior of the fiber ferrule 4 to form an optical fiber cantilever 22. The spiral regulator 5 is relatively fixed with the scanning fiber 2, and the scanning fiber 2 is relatively in slidable connection with the fiber ferrule 4. The spiral regulator 5 controls the scanning fiber 2 to move laterally by spinning in and spinning out along internal thread of the spiral regulator 5, so as to obtain a controllable optical fiber cantilever length. The piezoelectric ceramic driver 6 is arranged outside the scanner, and comprises a signal generator and an amplifier. The signal generator is used for generating an alternating current signal to obtain a required driving signal for the scanning fiber 2 by means of regulating amplitude of the alternating current signal and phase parameter; and the driving signal comprises a scanning range and a scanning track mode which are used for driving the scanning fiber. The amplifier is used for amplifying the low power driving signal outputted by the signal generator. The micro scanning square tube 3 receives amplified driving signal to drive the scanning fiber 2 to perform scanning according to the required scanning range and scanning track mode. The x, y are axial input channels. That is, the piezoelectric ceramic driver 6 applies the driving signal to the micro scanning square tube 3, so that the scanning fiber 2 performs resonance scanning along with vibration of the micro piezoelectric ceramic chips, and the micro scanning square tube 3, assembled by the micro piezoelectric ceramic chips, drives the optical fiber cantilever 22 to perform resonance scanning. And the fixing collar 7 and the packaging sleeve 8 are used for fixing and packaging the tunable fiber scanner.

Specifically, a suspension end of the fiber connector 1 is connected to a nonlinear microscopic imaging excitation source 13, the fiber connector 1 can efficiently connect the optical path due to its low insertion loss and high repetition characteristics.

Specifically, the micro scanning square tube 3 is assembled by four micro piezoelectric ceramic chips 31,32,33,34 via a mold auxiliary assembly process; length of the micro piezoelectric ceramic chip ranges from 17 mm to 26 mm, width of which is 1.5 mm, thickness of which ranges from 0.3 mm to 0.7 mm. During preparation, polarization directions of the two opposite micro piezoelectric ceramic chips 31,32,33,34 need to be kept consistent, and outer walls of the two opposite micro piezoelectric ceramic chips are provided with same alternating current signal by the piezoelectric ceramic driver 5 and have the same driving voltage waveform signal. The inner walls of the micro piezoelectric ceramic chips are connected to an integral electrode by means of a copper powder conductive adhesive and grounded, and the length of the copper powder conductive adhesive covering the inner wall is 2 mm to 3 mm. Actual resonance frequency of the optical fiber cantilever 22 is obtained by means of a frequency sweep test, and scanning of the micro scanning square tube 3 performed at the resonance frequency.

Specifically, if structure asymmetry occurs in the micro scanning square tube 3, a compensated driving signal is applied to achieve stable operation of the scanning fiber 2.

Specifically, the scanning fiber is used for optical path transmission and resonance scanning. The type of the fiber in the scanner can be single mode optical fiber, multimode optical fiber, multi-core optical fibers, micro-structure optical fiber, and the like.

Specifically, the length of the optical fiber cantilever 22 is tuned by the spiral regulator 5, and the tuning range ranges from 5 mm to17 mm, and is determined by the required scanning frequency.

Specifically, the outer diameter of the fiber ferrule 4 is consistent with the width of the micro piezoelectric ceramic chip, the inner wall of the micro scanning square tube 3 is tightly fitted with the fiber ferrule 4.

The spiral regulator 5 tunes the length of the optical fiber cantilever and the resonance frequency according to the principle of spiral amplification. A nut 15 at the rear end of the spiral regulator 5 and the micro scanning square tube 3 are fixed via epoxy resin glue 9, a rectangular hole 14 is provided on the packaging sleeve 8 for leading out a wire 35, the scanning fiber 2 is slidable in the hole 14. A screw 16 at the front end of the spiral regulator 5 is relatively fixed with the scanning fiber 2. By rotating a handle 17 located at the tail end of the scanner, the screw 16 can rotate on the nut 15 to drive the scanning fiber 2 to move along the central axis of the scanner, thereby achieving the length regulation and resonance frequency tuning. The screw 16 at the front end rotates one revolution on the nut, and the screw moves forward or backward a thread distance, that is, 1 mm, which is also the distance between every two circular marking positions on the screw 16. The screw 16 has 100 evenly divided scales for each rotation, and the optical fiber cantilever is advanced or retracted by 0.01 mm for every rotation. The magnitude of the length of the optical fiber cantilever can be determined according to the number of the circular marking positions at the outside of the packaging sleeve 8. According to the alignment of the linear scale of the spiral regulator 5 and the circular marking position of the packaging sleeve 8, the number can be accurate to 0.01 mm. Since the reading position can also be re-estimated, the total length of the optical fiber cantilever can be read to thousands of positions of millimeters.

The total length of the fixing collar 7 is 4 mm, the outer wall is cylindrical, a square aperture is provided inside, and the size is adapted to the micro piezoelectric ceramic chips, and the fixing collar 7 is tightly fixed with the packaging sleeve 8 and the micro scanning square tube 3. The packaging sleeve 8 is a stainless steel tube, and is used for protecting the micro scanning square tube 3 and the spiral regulator 5, the packaging sleeve 8 has a total length of 40 mm, a wall thickness of 0.5 mm, inner diameter matches the size of the fixing collar 7, a 5 mm long opening is provided in the middle, a position of 10-15 mm from both ends, for leading out the wire. An end of the outer wall of the packaging sleeve close to the spiral regulator 5 is etched with a 0-scale marking position, the 0-scale marking position is used for reading when use cooperatively with the marking positions of the spiral regulator 5, and when the length of the optical fiber cantilever is an integer millimeter length, the 0-scale marking position of the packaging sleeve is aligned with the 0-scale marking position of the spiral regulator.

For different applications, different sizes of micro piezoelectric ceramic chips are applied to prepare the micro scanning square tube, or driving signals are changed to satisfy different imaging requirements, or change the length of the optical fiber cantilever 22 by the spiral regulator 5 to regulate resonant frequency, so as to regulating scanning speed and imaging frame rate.

According to the drawings of the tunable fiber scanner for an all-fiber nonlinear microspectrometer, the scanner comprises the fiber connector 1, the scanning fiber 2, the micro scanning square tube 3 assembled by micro piezoelectric ceramic chips, the fiber ferrule 4, the spiral regulator 5, the piezoelectric ceramic driver 6, the fixing collar 7 and the packaging sleeve 8.

The preparation method of the tunable fiber scanner for an all-fiber nonlinear microspectrometer, including:

Step 1: preparing plastic clay 10, embedding rubber 11 into the plastic clay 10, exposing edges of right angles to facilitate arranging the micro piezoelectric ceramic chips; applying a small amount of mixed epoxy resin glue by using a steel needle on the edges of two micro piezoelectric ceramic chips; placing the micro piezoelectric ceramic chips having a small amount of the epoxy resin glue on one end of the right-angled edge of the rubber 11 gently, then adding the amount of the glue to the edges where the micro piezoelectric ceramic chips are connected when the chips are stable; and fixing for 24 hours to form a stable L-shaped structure;

Step 2: placing the L-shaped structure in a groove of the glass mold gently, one micro piezoelectric ceramic chip of the L-shaped structure is tightly attached to the glass of the glass mold, the other micro piezoelectric ceramic chip is above the groove. The groove in the middle of the glass mold is specially designed, and its length is equal to that of the micro piezoelectric ceramic chip, which enables the micro piezoelectric ceramic chips to be stably placed therein. Placing the fiber ferrule 4 under the L-shaped structure, tightly attached to the glass, to support the L-shaped structure; evenly applying epoxy resin glue 9 on the edges of a third micro piezoelectric ceramic chip by the steel needle, and placing the third micro piezoelectric ceramic chip on the other side of the L-shaped structure, and tightly attaching to the fiber ferrule and the micro piezoelectric ceramic chip located on the top, and fixing for 24 hours to form a U-shaped groove;

Step 3: cutting after peeling off a coating at one end of the scanning fiber 2, an optical fiber cutting knife is adopted to ensure that the end face of the optical fiber cantilever is flat and smooth; inserting the scanning fiber 2 into the fiber ferrule 4 to a specific cantilever length; placing the U-shaped groove upside down, facing the side of the U-shaped groove without the micro piezoelectric ceramic chips upwardly; placing the fiber ferrule 4 with the scanning fiber 2 in the U-shaped groove, and fixing the fiber ferrule and U-shaped groove by epoxy resin glue 9; and placing a fourth micro piezoelectric ceramic chip onto the top of the U-shaped groove, evenly applying epoxy resin glue on the edges of the fourth micro piezoelectric ceramic chip to fix the fourth micro piezoelectric ceramic chip and the U-shaped groove, and fixing for 24 hours to form a stable micro scanning square tube 3 assembled by micro piezoelectric ceramic chips;

Step 4: fixing a cylindrical nut at the rear end of the micro scanning square tube 3 by the epoxy resin glue 9, penetrating the scanning fiber 2 through the micro scanning square tube, and configuring a screw to construct the spiral regulator 5; fixing the fixing collar 7 at the tail end of the micro scanning square tube 3 by the epoxy resin glue 9; a certain space is reserved to lead out a wire, finally, fixing the packaging sleeve 8 and the fixing collar 7 to ensure that a 0-scale marking position on the outer wall of the packaging sleeve is capable of aligning with the marking position of the spiral regulator when the screw is screwed tightly and the optical fiber cantilever reached maximum length, so as to form a four-piece assembled tunable piezoelectric-driven fiber scanner.

In summary, the four-piece assembled tunable piezoelectric-driven fiber scanner is made by a specific process flow, has the advantages such as easy mass production, low cost, and high electrical parameter control level. Compared with directly assembling an independent tubular structure vibration device with an optical fiber, the four-piece assembled tunable piezoelectric-driven fiber scanner has lower cost and more flexibility. For different applications, the size of the micro piezoelectric ceramic chips and types of the fiber can be adjusted during the preparation of the scanner so as to satisfy different imaging performances. The four-piece assembled structure makes the scanner convenient to fix different sizes of the fiber ferrule, thereby significantly improving the central symmetry and stability of the scanner, which is of great significance for the practical application of nonlinear microscopic imaging technology.

The above descriptions are only preferred implementations of the present disclosure. It should be noted that for those ordinarily skilled in the art, several improvements and modifications may be made without departing from the principles of the present disclosure, and these improvements and modifications should also fall within the scope of protection of the present disclosure.

What is claimed is:

1. A preparation method of the tunable fiber scanner for an all-fiber nonlinear microspectrometer, comprising:
Step 1: embedding rubber into plastic clay, exposing edges of right angles of the rubber, evenly applying a small amount of epoxy resin glue on the edges of the two micro piezoelectric ceramic chips (31,32,33,34), then adding the amount of the glue to the edges where the micro piezoelectric ceramic chips are connected, and fixing for 24 hours to form a stable L-shaped structure;
Step 2: placing the L-shaped structure in a groove of a glass mold, one micro piezoelectric ceramic chip of the L-shaped structure is tightly attached to the glass of the glass mold (12), the other micro piezoelectric ceramic chip is above the groove; placing a fiber ferrule (4) under the L-shaped structure, tightly attached to the glass, and supporting the L-shaped structure; evenly applying epoxy resin glue on the edges of a third micro piezoelectric ceramic chip and placing the third micro piezoelectric ceramic chip on the other side of the L-shaped structure, tightly attaching to the fiber ferrule (4) and the micro piezoelectric ceramic chip located on the top, and fixing for 24 hours to form a U-shaped groove;
Step 3: cutting after peeling off a coating at one end of a scanning fiber (2), so as to ensure the smoothness of an end of an optical fiber cantilever (22); inserting the scanning fiber into the fiber ferrule (4) to a specific cantilever length; placing the fiber ferrule (4) with the scanning fiber (2) in the upside-down U-shaped groove, and fixing the fiber ferrule (4) and U-shaped groove by epoxy resin glue; placing a fourth micro piezoelectric ceramic chip onto the top of the U-shaped groove, evenly applying epoxy resin glue on the edges of the fourth micro piezoelectric ceramic chip to fix the fourth micro piezoelectric ceramic chip and the U-shaped groove, and fixing for 24 hours to form a stable micro scanning square tube (3);
Step 4: fixing a cylindrical nut (15) at the rear end of the micro scanning square tube (3) by the epoxy resin glue, penetrating the scanning fiber through the micro scanning square tube (3), and configuring a screw to construct a spiral regulator (5); fixing a fixing collar (7) at the tail end of the micro scanning square tube (3) by the epoxy resin glue, a certain space is reserved to lead out a wire; and fixing a packaging sleeve (8) and the fixing collar (7) to ensure that a 0-scale marking position on the outer wall of the packaging sleeve (8) is capable of aligning with the marking position of the spiral regulator (5) when the screw is screwed tightly and the optical fiber cantilever reached maximum length, so as to form a four-piece assembled tunable piezoelectric-driven fiber scanner.

2. The preparation method according to claim 1, wherein the tunable fiber scanner for an all-fiber nonlinear microspectrometer comprises a scanning unit and a driving unit;
the scanning unit comprises a micro scanning square tube (3), the micro scanning square tube (3) is assembled by four micro piezoelectric ceramic chips (31,32,33,34); the fiber ferrule (4) is tightly sleeved in the micro scanning square tube (3), the spiral regulator (5) is fixed at the front end of the scanning fiber (2); and the rear end of the scanning fiber (2) penetrates through the interior of the fiber ferrule (4) to fix in the center of the micro scanning square tube (3); the fiber ferrule (4) is slidable relative to the scanning fiber so as to form an optical fiber cantilever (22);
the driving unit comprises a piezoelectric ceramic driver (6) arranged outside the scanner, the piezoelectric ceramic driver comprises a signal generator and an amplifier; wherein the signal generator is used for generating a driving signal, the amplifier is used for amplifying the driving signal outputted by the signal generator; the piezoelectric ceramic driver (6) applies amplified driving signal to the micro scanning square tube (3), and the micro scanning square tube receives the amplified driving signal to drive the scanning fiber to scan and drive the optical fiber cantilever to perform resonance scanning.

3. The preparation method according to claim 1, wherein if structure asymmetry occurs in the micro scanning square tube (3), a compensated driving signal is applied to achieve stable operation of the scanning fiber (2).

4. The preparation method according to claim 1, wherein the spiral regulator controls the scanning fiber to generate lateral movement to obtain a controllable length of the optical fiber cantilever (22).

5. The preparation method according to claim 1, wherein there are axial input channels x, y along the axial directions of the micro scanning square tube (3).

6. The preparation method according to claim 1, wherein the scanning fiber is connected with a fiber connector (1), and a suspension end of the fiber connector (1) is connected to a nonlinear microscopic imaging excitation source (13).

7. The preparation method according to claim 1, wherein polarization directions of the two opposite micro piezoelectric ceramic chips (31,32,33,34) are to be kept consistent, and outer walls of the two opposite micro piezoelectric ceramic chips are provided with same alternating current signal by the piezoelectric ceramic driver (5) and have the same driving voltage waveform signal.

8. The preparation method according to claim 1, wherein the inner walls of the micro piezoelectric ceramic chips (31,32,33,34) are connected to an integral electrode by means of a copper powder conductive adhesive and grounded, and the length of the copper powder conductive adhesive covering the inner walls ranges from 2 mm to 3 mm.

9. The preparation method according to claim 1, wherein the length of the optical fiber cantilever (22) is tuned by the spiral regulator (5), and the tuning range ranges from 5 mm to 17 mm.

10. The preparation method according to claim 1, wherein the outer diameter of the fiber ferrule (4) is consistent with the width of the micro piezoelectric ceramic chip, the inner wall of the micro scanning square tube (3) is tightly fitted with the fiber ferrule (4).
